(19) United States
(12) Patent Application Publication
(10) Pub. No.: US 2024/0188220 A1
(43) Pub. Date: Jun. 6, 2024

(54) TRANSPARENT CONDUCTING FILM AND METHOD FOR FORMING TRANSPARENT CONDUCTING PATTERN

(71) Applicant: RESONAC CORPORATION, Tokyo (JP)

(72) Inventors: Shigeru YAMAKI, Tokyo (JP); Shuhei YONEDA, Tokyo (JP); Yasunao MIYAMURA, Tokyo (JP); Kumiko TERAO, Tokyo (JP)

(73) Assignee: RESONAC CORPORATION, Tokyo (JP)

(21) Appl. No.: 18/285,001

(22) PCT Filed: Mar. 28, 2022
(86) PCT No.: PCT/JP2022/015138

§ 371 Date: Sep. 29, 2023

(30) Foreign Application Priority Data
Mar. 29, 2021 (JP) 2021-055393

(51) Int. Cl. H05K 3/02; H05K 1/09

(52) U.S. Cl. CPC H05K 3/027; H05K 1/095; H05K 2201/0215; H05K 2201/026

(57) ABSTRACT

First and second transparent conducting layers each containing a binder resin and a nano-structured network having metal nanowire intersections, are respectively formed on first and second main faces of a transparent resin film, each of the first and second transparent conducting layers has an absorption peak based on the nano-structured network in an optical transmission spectrum, the transparent resin film has a thickness of 40 μm or more. After first and second protection layers are respectively formed on the first and second transparent conducting layer, only the first transparent conducting layer is etched from the first protection layer side so that a first transparent conducting pattern having a first conducting region and a first non-conducting region is formed by the first transparent conducting layer on the first main face.

### TECHNICAL FIELD

The present disclosure relates to a transparent conducting film and a method for forming a transparent conducting pattern. In more deal, the present disclosure relates to a transparent conducting film having different transparent conducting patterns between one side and the other side of the film, and a method for forming a transparent conducting film having different patterns between one side and the other side of the film.

### BACKGROUND ART

Recently, touch panels are adopted for smartphones, car navigation systems, vending machines, etc. In particular, since a foldable smartphone attracts attention, there is a desire for a foldable touch panel.

In order to obtain a foldable touch panel, a foldable transparent film and transparent conducting layer, namely, a transparent conducting film having a superior durability of folding is necessary. A transparent conducting film with the smallest possible thickness is desirable. If the film thickness is too large, the film is easily broken when it is folded.

One way of obtaining a transparent conducting film with a small thickness may be providing a conducting layer on each of the opposite main faces of a substrate. This is because, if a conducting layer is provided on each of the opposite main faces of a substrate, one transparent conducting film can act as both of a X sensor and a Y sensor. Whereas, in case of a transparent conducting film having a conducting layer on one of the main faces of the substrate, two films must be adhered for use, resulting in enlarging the total film thickness.

When a transparent conducting film is made into a sensor, in general, a conducting layer that is a solid pattern film, needs to be subjected to etching to form a wire pattern.

Etching methods can be roughly classified in two kinds which are dry-etching (laser) and wet-etching. In view of the environmental load such as generation of waste liquid, etc., caused by the wet-etching, the former, i.e., the laser-etching, is superior.

Namely, in order to obtain a foldable touch panel, manufacturing a transparent conducting film having a transparent resin film used as a substrate, each of the main faces of the transparent resin film being provided with a transparent conducting layer; and patterning each of the transparent conducting layers by laser-etching, are necessary.

However, there is a problem that in case that a transparent resin film having a small thickness is used as a substrate, when the laser-etching is applied to the transparent conducting layer provided on one main face, laser rays penetrate through the substrate (transparent resin film) and the transparent conducting layer provided on the other side, i.e., opposite to the treated side, is also treated.

A method for patterning, by laser-etching, a transparent conducting film having a polycarbonate substrate on which a silver nanowire layer is formed is already known (Patent Document 1). However, there is no description of an example wherein the laser-etching is applied to both of the main faces of one substrate. Namely, the problem to be solved by the present disclosure is not recognized.

A method for preventing the laser from penetrating through a transparent conducting film, by increasing the thickness of a transparent substrate, made of a polymer material, of the transparent conducting film, and reducing the energy density by 50% or more (Patent Document 2). In the specification of Patent Document 2, examples of laser wavelengths and polymer materials which can be used for the transparent substrate are shown. However, actual results obtained by etching the conducting layer are not shown. Therefore, whether a desired treatment can be achieved by the disclosed method is not known at all.

The applicant disclosed, in Patent Document 3, a transparent conducting substrate having a substrate, a transparent conducting layer formed at least on one main face of the substrate and containing a binder resin and conductive fibers (metal nanowires), and a protection layer formed on the transparent conducting layer. However, the problem to be solved by the disclosure of Patent Document 3 is providing a transparent conducting substrate having a superior optical property, electrical property, and further, superior light resistance, which is completely different from the problem to be solved by the present disclosure.

### PRIOR ARTS

Patent Document 1: Japanese Unexamined Patent Publication (Kokai) No. 2015-15009

Patent Document 2: US 2020/0409486

Patent Document 3: WO 2018/101334

### SUMMARY

One of the objectives of the present disclosure is to provide a transparent conducting film having a transparent resin film as a substrate, and transparent conducting patterns respectively provided on both of the main faces of the transparent resin film, the patterns being different from each other. Another objective is to provide a method for forming transparent conducting patterns, using a transparent resin film having transparent conducting layers respectively formed on both of the main faces of the transparent resin film, the transparent conducting patterns being different from each other.

In order to attain the above objectives, the present disclosure has following aspects.
[1] A transparent conducting film comprising a transparent resin film as a substrate, a first transparent conducting pattern layer provided on a first main face of the transparent resin film, a second transparent conducting pattern layer provided on a second main face of the transparent resin film and having a pattern different from the patten of the first transparent conducting pattern layer, a first protection layer provided on the first transparent conducting pattern layer, and a second protection layer provided on the second transparent conducting pattern layer, respectively, wherein, the first transparent conducting pattern layer consists of a first conducting region and a first non-conducting region, the first conducting region contains a binder resin and a nano-structured network having metal nanowire intersections, the second transparent conducting pattern layer has a second conducting region, the second conducting region containing a binder resin and a nano-structured network having metal nanowire intersections, the first transparent conducting pattern layer has an absorption peak based on the nano-structured network, in an optical transmission spectrum, the transparent resin film has a light transmittance of 80% or more in a wavelength region of ±30 nm from an absorption peak maximum wavelength based on the nano-structured network in the optical transmission spectrum and in a visible light region, and has a thickness of 40 μm or more.
[2] A transparent conducting film according to [1], wherein the second transparent conducting pattern layer further comprises a second non-conducting region, and the second transparent conducting pattern layer has an absorption peak based on the nano-structured network in the optical transmission spectrum.
[3] A transparent conducting film according to [1], wherein the first non-conducting region contains a fragment of the nano-structured network having metal nanowire intersections.
[4] A transparent conducting film according to [2], wherein the second non-conducting region contains a fragment of the nano-structured network having metal nanowire intersections.
[5] A transparent conducting film according to any one of [1] to [4], wherein the transparent resin film has a thickness of 200 um or less.
[6] A transparent conducting film according to any one of [1] to [5], wherein the transparent resin film is a resin selected from a group consisting of a cyclo olefin polymer, polycarbonate, polyester, polyolefin, polyaramid, and acrylic resin.
[7] A transparent conducting film according to any one of [1] to [6], wherein, in the nano-structured network having metal nanowire intersections, at least a part of the metal nanowire intersections is fused.
[8] A transparent conducting film according to any one of [1] to [7], wherein the metal nanowire is a silver nanowire.
[9] A transparent conducting film according to any one of [1] to [8], wherein the binder resin is a homopolymer of N-vinylacetamide (NVA).
[10] A transparent conducting film according to any one of [1] to [9], wherein the first protection layer and the second protection layer are thermoset layers of a curable resin composition containing: (A) polyurethane containing a carboxyl group, (B) an epoxy compound having two or more epoxy groups in a molecule, and (C) a curing accelerator.
[11] A method for forming a transparent conducting pattern comprising:
   a transparent conducting layer forming step for forming a first transparent conducting layer containing a binder resin and a nano-structured network having metal nanowire intersections, on a first main face of a transparent resin film, and forming a second transparent conducting layer containing a binder resin and a nano-structured network having metal nanowire intersections, on a second main face of the transparent resin film, respectively, a protection layer forming step for forming a first protection layer on the first transparent conducting layer, and forming a second protection layer on the second transparent conducting layer, respectively, and a pattern forming step for forming a first transparent conducting pattern by etching only the first transparent conducting layer from the first protection layer side using pulse laser having a pulse width of shorter than 1 nanosecond, wherein the first transparent conducting layer and the second transparent conducting layer respectively has an absorption peak based on the nano-structured network in an optical transmission spectrum, the transparent resin film has a light transmittance of 80% or more in a wavelength region of ±30 nm from an absorption peak maximum wavelength based on the nano-structured network in the optical transmission spectrum and in a visible light region, and has a thickness of 40 μm or more, and the pulse laser has a wavelength within a range of ±30 nm from the absorption peak maximum wavelength based on the nano-structured network in the optical transmission spectrum.
[12] A method for forming a transparent conducting

pattern according to [11], further comprising a step for forming a second transparent conducting pattern by etching only the second transparent conducting layer from the second protection layer side using pulse laser having a pulse width of shorter than 1 nanosecond.

According to the transparent conducting film of the present disclosure, only the transparent conducting layer on one of the main faces of the transparent resin film as a substrate can be selectively treated by laser-etching. Therefore, the processability of forming transparent conducting patterns different between both main faces is extremely superior. As a result, a transparent conducting film having a transparent resin film as a substrate, and transparent conducting patterns being different from each other and respectively provided on both of the main faces of the transparent resin film, can be provided. Also, a method for forming transparent conducting patterns which are different from each other, on respective main faces of the transparent conducting film, can be provided.

### BRIEF DESCRIPTION OF DRAWINGS

FIG. 1 shows optical transmission spectra when COP is used for a transparent resin film, and a silver nanowire (AgNW) is used as a metal nanowire.

FIG. 2 shows a cross-sectional view of an intersection of silver nanowires in a nano-structured network which constitutes a transparent conducting pattern in the transparent conducting film according to the present aspect.

FIG. 3 is a view showing an observation visual field of electron-beam diffraction of a nano-structured network constituting the transparent conducting pattern in the transparent conducting film according to the present aspect.

FIG. 4 is a view showing an electron-beam diffraction observation result (diffraction pattern) of silver nanowire distant from a silver nanowire intersection in the nano-structured network constituting the transparent conducting pattern in the transparent conducting film according to the present aspect.

FIG. 5 is a view showing an electron-beam diffraction observation result (diffraction pattern disappearance) near a silver nanowire intersection in the nano-structured network constituting the transparent conducting pattern in the transparent conducting film according to the present aspect.

FIG. 6 is a view showing an electron-beam diffraction observation result (diffraction pattern) of a silver nanowire intersection in the nano-structured network constituting the transparent conducting pattern in the transparent conducting film according to the present aspect.

FIG. 7 is an explanatory view of a conduction confirmation method regarding laser-treated surfaces of the transparent conducting films produced by Examples and Comparative Examples.

FIG. 8 is a view showing an image of evaluation regarding the transparent conducting films produced by an example treatment and a comparative example of treatment.

### ASPECTS OF DISCLOSURE

Hereinbelow, aspects of the present disclosure (hereinbelow, referred to as aspects) will be explained.

A transparent conducting film according to the first aspect of the present disclosure comprises a transparent resin film as a substrate, a first transparent conducting pattern layer located on a first main face of the transparent resin film, a second transparent conducting pattern layer located on a second main face of the transparent resin film, the pattern of the second transparent conducting pattern layer being different from the pattern of the first transparent conducting pattern, a first protection layer located on the first transparent conducting pattern layer, and a second protection layer located on the second transparent conducting pattern layer, wherein the first transparent conducting pattern layer comprises a first conducting region and a first non-conducting region, the first conducting region containing a binder resin and a nano-structured network having metal nanowire intersections, the second transparent conducting pattern layer comprise a second conducting region, the second conducting region containing a binder resin and a nano-structured network having metal nanowire intersections, the first transparent conducting layer has an absorption peak based on the nano-structured network in an optical transmission spectrum, the transparent resin film has a light transmittance of 80% or more in a wavelength region within ±30 nm from an absorption peak maximum wavelength based on the nano-structured network in the optical transmission spectrum and in a visible light region, and has a thickness of 40 μm or more.

In the present specification the term “transparent” refers to that the light transmittance (total light transmittance) in the visible light (wavelength 400 to 700 nm) region is 80% or more.

### <Transparent Resin Film (Substrate for Transparent Conducting Film)>

A transparent resin film used for a substrate of the transparent conducting film according to the first aspect of the present disclosure has a light transmittance of 80% or more in the wavelength region within ±30 nm from the absorption peak maximum wavelength in the optical transmission spectrum of a below-mentioned nano-structured network having metal nanowire intersections and contained in a transparent conducting layer and in the visible light region (region with a wavelength of 400 nm to 700 nm), and has a thickness of 40 μm or more. In order to obtain a transparent conducting film, a resin film itself, which is used for a substrate, should be transparent. Thus, the above-mentioned light transmittance is 80% or more, preferable 85% or more, and more preferably 88% or more. Since the transparent resin film has a thickness of 40 μm or more, even if a transparent resin film is used, penetration of the below-mentioned pulse-shaped laser light (hereinbelow, may be referred to as pulse laser) can be prevented. As the transparent resin film is thicker, the effect for preventing the penetration of the pulse-shaped laser light is increased. However, in view of the application to a foldable smartphone (bending resistance), the thinner film is the more advantageous. The thickness of the transparent resin film preferably 45 to 200 μm, more preferably 50 to 125 μm, and still more preferably 100 to 125 μm.

The kind of resin for the transparent resin film is not limited as far as far as the resin is transparent and non-conducive. Examples of the resin include cyclo olefin polymer, polycarbonate [PC], polyester (polyethylene terephthalate [PET], polyethylene naphthalate [PEN], etc.), polyolefin (polyethylene [PE], polypropylene [PP], etc.), polyaramid, acrylic resin (poly methyl methacrylate [PMMA], etc.). As far as the optical property and the electric property are not damaged, the transparent resin film may be provided with a single or a plurality of layers having functions of easy adhesion, hard coating, and the like, on one or both of the main faces. Among these transparent resin films, in view of a superior optical property (low haze, low retardation), using a cyclo olefin polymer film is preferable.

A cyclo olefin polymer is a polymer synthesized by using cyclo olefins such as norbornene as a monomer, and has an alicyclic structure in a molecular structure. The cyclo olefin polymer may be a hydrogenated ring-opening metathesis polymerization type of norbornene derivative [COP] or an addition polymerization type with ethylene [COC]. According to the present aspect, from the viewpoints of the heat resistance and folding durability, the hydrogenated ring-opening metathesis polymerization type [COP] is more preferable. Examples of the hydrogenated ring-opening metathesis polymerization type [COP] include ZEONEX (registered trademark) manufactured by Zeon Corporation, ZEONOR (registered trademark), manufactured by Zeon Corporation, ARTON (registered trademark) manufactured by JSR Corporation, etc.

### <Transparent Conducting Pattern>

The transparent conducting film according to the first aspect of the present disclosure has a transparent resin film which is a substrate, the transparent resin film being provided on its first main face with a first transparent conducting pattern layer, and on its second main face with a second transparent conducting pattern layer, respectively. The first transparent conducting pattern layer has a first conducting region and a first non-conducting region. The first conducting region is formed by one or a plurality of conducting parts, and the first non-conducting region is formed by one or a plurality of non-conducting parts. The first transparent conducting pattern layer is different from the second transparent conducting pattern layer formed on the second main face side. Here, the description that “first transparent conducting pattern layer is different from the second transparent conducting pattern layer” refers to the state that projection positions of the first conducting region and the first non-conducting region in the first transparent conducting pattern layer toward the second main face side are not, respectively, identical with positions of the second conducting region and the second non-conducting region in the second transparent conducting pattern layer formed on the second main face side. The second transparent conducting pattern layer may only have the second conducting region, or may have the second conducting region and the second non-conducting region. When the second transparent conducting pattern layer has the second conducting region only, the second transparent conducting pattern layer formed on the second main face side is a solid transparent conducting layer. Whereas, if the second transparent conducting pattern layer has the second conducting region and the second non-conducting region, the second conducting region is formed by one or a plurality of conducting parts, and the second non-conducting region is formed by one or a plurality of non-conducting part.

The first conducting region includes a nano-structured network having metal nanowire intersections, as well as a binder resin. Whereas, the second conducting region includes a nano-structured network having metal nanowire intersections, as well as a binder resin. Preferably, each of the first and second transparent conducting layers is structured to include a nano-structured network in which at least part of the metal nanowire intersections are fused. A method for constituting the nano-structured network may be coating a metal nanowire dispersion liquid (metal nanowire ink) on a substrate (transparent resin film), and drying the liquid. Preferably, a heating process or a photoirradiation process may be performed to fuse at least part of the metal nanowire intersections. The state that the metal nanowire intersections are fused can be confirmed by analyzing an electron-beam diffraction pattern of a transmission electron microscope (TEM), that is, specifically, by analyzing an electron-beam diffraction pattern of a portion where metal nanowires intersect, and confirming the change of crystal structure (generation of recrystallization).

If the above-mentioned first and second non-conducting regions are formed by processing the transparent conducting layer with the pulse laser, using a transparent conducting pattern forming method, which is a second aspect of the present disclosure method below, the metal which forms the nano-structured network having metal nanowire intersections and constituting the transparent conducting layers located in ranges made into the non-conducting regions by the pulse laser irradiation, is fused. Thus, a network structure sufficient to develop conductivity cannot be maintained, and the region to which the pulse laser is irradiated becomes a non-conducting region. The wire-shaped metal constituting the nano-structured network is broken, and the non-conducting region includes segments of the nano-structured network. The segments have various shapes. For example, the segment may have a particle shape (spherical, ellipsoidal, columnar, etc.) formed by breaking the metal nanowire. The segment may be the one formed by finely breaking the metal nanowire to the extent that the non-conducting region as a whole becomes non-conductive although the network structure (including metal nanowire intersections) partly remains (such as an intersection of the metal nanowire (such as a cross-shaped segment), etc.). Completely removing the segments of the nano-structured network present in the non-conducting region is possible. However, if the segments are completely removed, the contrast between the conducting region and the non-conducting region becomes high, and thus, the visibility becomes lowered (pattern visibility easily occurs). Therefore, preferably, all the segments should not be removed.

As a method for producing the metal nanowire, a known method may be applied. For example, silver nanowires may be synthesized by reducing the silver nitrate under the presence of polyvinylpyrrolidone, using a poly-ol method (refer to Chem. Mater., 2002, 14, 4736). Similarly, gold nanowires may be synthesized by reducing the gold chloride acid hydrate under the presence of polyvinylpyrrolidone (refer to J. Am. Chem. Soc., 2007, 129, 1733). WO 2008/073143 pamphlet and WO 2008/046058 pamphlet have detailed description regarding the technology of large scale synthesis and purification of silver nanowires and gold nanowires. Gold nanotubes having a porous structure may be synthesized by using silver nanowires as templates, and reducing a gold chloride acid solution. The silver nanowires used as templates are dissolved in the solution by oxidation-reduction reaction with the gold chloride acid, and as a result, gold nanotubes having a porous structure can be produced (refer to J. Am. Chem. Soc., 2004, 126, 3892-3901).

The metal nanowires have an average diameter size of preferably 1 to 500 nm, more preferably 5 to 200 nm, still more preferably 5 to 100 nm, and particularly preferably 10 to 50 nm. The metal nanowires have an average major axis length of preferably 1 to 100 μm, more preferably 1 to 80 μm, still more preferably 2 to 70 μm, and particularly preferably 5 to 50 μm. While satisfying the above ranges of the average diameter size and the average major axis length, the metal nanowires have an average aspect ratio of preferably more than 5, more preferably 10 or more, still more preferably 100 or more, and particularly preferably 200 or more. Here, the aspect ratio refers to a value obtained by a/b, wherein “b” represents an average diameter size of the metal nanowire and “a” represents an average major axis length thereof. The values “a” and “b” may be measured by a scanning electron microscope (SEM) and an optical microscope. Specifically, “b” (average diameter) is obtained by measuring diameters of any selected 100 silver nanowires respectively using the Field Emission Scanning Electron Microscope JSM-7000F (manufactured by JEOL Ltd.), and calculating the arithmetic average thereof. Further, “a” (average length) is obtained by measuring lengths of any selected 100 silver nanowires respectively using the Shape Measurement Laser Microscope VK-X200 (manufactured by Keyence Corporation), and calculating the arithmetic average thereof.

The kind of the metal as a material for the metal nanowires may be one selected from the group consisting of gold, silver, platinum, copper, nickel, iron, cobalt, zinc, ruthenium, rhodium, palladium, cadmium, osmium, and iridium, or may be an alloy etc., formed by combining some of these. In order to obtain a coating film having a low sheet resistance and a high total light transmittance, containing at least one of gold, silver, and copper is preferable. These metals have a high conductivity, and thus, when a certain sheet resistance should be obtained, the density of the metal within the surface may be reduced, and high total light transmittance can be achieved. Among these metals, containing at least gold or silver is more preferable. The most appropriate example may be the silver nanowire.

As for the binder resin, any transparent binder can be used with no limitation. In case that metal nanowire produced by the poly-ol method is used, a binder resin soluble in alcohol, water, or a mixture solvent of alcohol and water is preferable, in view of the compatibility to the solvent for production (polyol). Specific examples include: poly-N-vinyl pyrrolidone, a hydrophilic cellulose resin such as methyl cellulose, hydroxyethyl cellulose, carboxymethyl cellulose, and the like, a butyral resin, or poly-N-vinylacetamide (PNVA (registered trademark)). Poly-N-vinylacetamide is a homopolymer of N-vinylacetamide (NVA). N-vinylacetamide copolymer having 70 mol % or more of N-vinylacetamide (NVA) may also be used. Examples of a monomer which can be copolymerized with NVA include: N-vinylformamide, N-vinylpyrrolidone, acrylic acid, methacrylic acid, sodium acrylate, sodium methacrylate, acrylamide, acrylonitrile, and the like. The more the content of the copolymerized component, the higher the sheet resistance of the transparent conducting layer to be obtained, the lower the miscibility to the metal nanowires or the adhesion to the substrate, and the lower the heat resistance (thermal decomposition starting temperature). Therefore, the polymer contains the monomer unit derived from N-vinylacetamide preferably 70 mol % or more, more preferably 80 mol % or more, and still more preferably 90 mol % or more. The polymer has a weight average molecular weight in terms of absolute molecular weight of preferably 30,000 to 4,000,000, more preferably 100,000 to 3,000,000, and still more preferably 300,000 to 1,500,000. When the binder resin is water soluble, the absolute molecular weight is measured by the following method.

### <Measurement of Absolute Molecular Weight>

A binder resin is dissolved in the following eluent, and is left to stand for 20 hours. In the solution, the concentration of the binder resin is 0.05% by mass.

The solution is filtered by a 0.45 μm membrane filter, and the filtrate is analyzed by GPC-MALS, and a weight average molecular weight in terms of the absolute molecular weight is calculated.
GPC: Shodex (Registered Trademark) SYSTEM21, manufactured by Showa Denko K. K.
Column: TSKgel (Registered Trademark) G6000PW manufactured by Tosoh Corporation
Column Temperature: 40° C.
Eluent: 0.1 mol/L NaH₂PO₄ aqueous solution+0.1 mol/L Na₂HPO₄ aqueous solution
Flow Rate: 0.64 mL/min
Sample Injection Amount: 100 μL
MALS Detector: Wyatt Technology Corporation, DAWN (registered trademark) DSP
Laser Wavelength: 633 nm
Multiangle Fitting Method: Berry Method

One of the above resins may be used solely, but two or more types of the resins may be used in combination. When two or more types of resins are used in combination, the combination may be a simple mixing, or may be a copolymer.

As mentioned above, each of the first and second transparent conducting layers contains a nano-structured network having metal nanowire intersections, and a binder resin. Each of the first and second transparent conducting layer is formed by coating, such as printing, a metal nanowire ink containing a solvent in which metal nanowires are evenly dispersed and the binder resin is dissolved, on both main faces of the transparent resin film, respectively, and removing the solvent by drying.

The solvent is not limited as far as the metal nanowires can be preferably dispersed therein, the binder resin can be dissolved therein, and the transparent resin film cannot be dissolved therein. When metal nanowires synthesized by the polyol method are used, taking into account the compatibility with the production solvent (polyol), alcohol, water, or a mixed solvent of alcohol and water are preferable. As mentioned above, a preferable binder resin is also the one soluble in alcohol, water, or a mixed solvent of alcohol and water. From the viewpoint of easily controlling the drying speed of the binder resin, using a mixed solvent of alcohol and water is more preferable. The alcohol preferably includes at least one type of saturated monohydric alcohols having 1 to 3 carbon atoms (methanol, ethanol, n-propanol, isopropanol), which are represented by CₙH₂ₙ₊₁OH (n being an integer of 1 to 3) [hereinbelow, merely described as “saturated monohydric alcohol having 1 to 3 carbon atoms”]. The saturated monohydric alcohol having 1 to 3 carbon atoms is contained preferably 40% by mass or more in the alcohol in total. Using the saturated monohydric alcohol having 1 to 3 carbon atoms is advantageous because drying of the solvent becomes easy. Alcohols other than the saturated monohydric alcohol having 1 to 3 carbon atoms can be used together. Examples of other alcohols which can be used together with the saturated monohydric alcohol having 1 to 3 carbon atoms include ethylene glycol, propylene glycol, ethylene glycol monomethylether, ethylene glycol monoethylether, propylene glycol monomethylether, propylene glycol monoethylether, and the like. Using such alcohol together with the saturated monohydric alcohol having 1 to 3 carbon atoms is advantageous because the drying speed of the solvent can be adjusted. The content of the total alcohol in the mixed solvent is preferably 5% to 90% by mass. If the alcohol content in the mixed solvent is less than 5% by mass or more than 90% by mass, there are drawbacks such that a strip pattern (uneven coating) is generated at the time of coating.

The metal nanowire ink can be produced by stirring and mixing the binder resin, the metal nanowires, and the solvent, using a planetary centrifugal stirrer, etc. The content of the binder resin in the metal nanowire ink is preferably in the range of 0.01% to 1.0% by mass. The content of the metal nanowires contained in the metal nanowire ink is preferably in the range of 0.01% to 1.0% by mass. The content of the solvent in the metal nanowire ink is preferably in the range of 98.0% to 99.98% by mass.

The metal nanowire ink may be printed by a bar-coating method, spin-coating method, spray coating method, gravure printing, slit coating, and the like. The shape of a printed film or pattern formed by printing is not particularly limited, but may be a shape of wiring or electrode pattern formed on the substrate, a shape of a film covering the entirety or a part of the substrate (solid paint pattern), or the like. The formed pattern can be made conductive by drying the solvent. The preferable thickness of transparent conducting layer or the transparent conducting pattern obtained after the solvent is dried may be different depending on the diameter of the metal nanowire used, or a desired sheet resistance value, but the thickness is preferably 10 to 300 nm, and more preferably 30 to 200 nm. If the dry thickness of the transparent conducting layer is larger than 10 nm, the number of intersections of the metal nanowires increases, resulting in showing preferable conductivity. If the dry thickness of the transparent conducting layer is 300 nm or less, more light can be transmitted and reflection by the metal nanowire is suppressed, and thus, a preferable optical property can be obtained. In accordance with needs, an appropriate heating or photoirradiation may be applied to the conducting pattern.

### <Protection Layer>

A transparent conducting film according to the first aspect of the present disclosure has a first protection layer on the first transparent conducting pattern layer, and a second protection layer on the second transparent conducting pattern layer, respectively. The protection layer which protects the transparent conducting pattern layer is a thermal cured film of a curable resin composition. The curable resin composition preferably contains (A) a polyurethane containing a carboxyl group, (B) an epoxy compound having two or more epoxy groups in a molecule, and (C) a curing accelerator. The curable resin composition is formed on the first and second transparent conducting pattern layers by printing, coating, etc., and is cured to form a protection layer. Curing of the curable resin composition can be performed, when a thermosetting resin composition is used, by heating and drying the thermosetting resin composition. Hereinbelow, “(B) an epoxy compound having two or more epoxy groups in a molecule” will be simply referred to by “(B) an epoxy compound”.

### (A) Polyurethane Containing Carboxyl Group

The (A) polyurethane containing a carboxyl group has a weight average molecular weight of preferably 1,000 to 100,000, more preferably 2,000 to 70,000, and still more preferably 3,000 to 50, 000. In the present specification, the weight average molecular weight of the polyurethane containing a carboxyl group is a polystyrene equivalent value measured by GPC. If the weight average molecular weight of the polyurethane containing a carboxyl group is 1,000 or more, the elongation property, the flexibility, and the strength of the coated film after printing may be sufficiently realized. Whereas, if the molecular weight of the polyurethane containing a carboxyl group is 100,000 or less, the solubility of polyurethane to the solvent is favorable, and a polyurethan solution obtained after the polyurethan is dissolved does not have a too high viscosity, and has a superior handling property.

In the present specification, the measurement conditions of GPC used for measuring the polyurethane containing a carboxyl group are as follows, unless otherwise described specifically:
Device Name: HPLC unit HSS-2000, manufactured by JASCO Corporation
Column: Shodex Column LF-804
Mobile Phase: tetrahydrofuran
Flow Rate: 1.0 mL/min
Detector: RI-2031 Plus manufactured by JASCO Corporation
Temperature: 40.0° C.
Sample Volume: sample loop 100 μL
Sample Concentration: Prepared to approximately 0.1% by mass

The (A) polyurethane containing a carboxyl group has an acid value of preferably 10 to 140 mg-KOH/g, and more preferably 15 to 130 mg-KOH/g. If the acid value of the polyurethane containing a carboxyl group is 10 mg-KOH/g or more, the protection layer has a preferable solvent resistance, and the resin composition has a preferable curing property. Whereas, if the acid value of the polyurethane containing a carboxyl group is 140 mg-KOH/g or less, the solubility of the polyurethane to the solvent is preferable, and the viscosity of the resin composition can be easily adjusted to a desired viscosity. In addition, problems such as warpage, etc., of the substrate film caused by the too hard cured product can be avoided.

In the present specification, the acid value of the polyurethane containing a carboxyl group is a value measured by the following method.

Approximately 0.2 g of a sample is precisely weighed by a precision balance into a 100 ml Erlenmeyer flask, and 10 ml of a mixture solvent of ethanol/toluene=½ (mass ratio) is provided thereto to dissolve the sample. Further, 1 to 3 drops of a phenolphthalein ethanol solution is added to the container as an indicator, which is sufficiently stirred until the sample becomes uniform. The resultant is subjected to titration with a 0.1 N potassium hydroxide-ethanol solution. When the indicator continues to be in light red for 30 seconds, it is determined that the neutralization ends. The value obtained from the result using the following calculation formula is treated as an acid value of the polyurethane containing a carboxyl group.

Acid Value (mg−KOH/g)=[B×f×5.611]/S
B: Use amount (ml) of 0.1 N potassium hydroxide-ethanol solution
f: Factor of 0.1 N potassium hydroxide-ethanol solution
S: Collection quantity (g) of sample

More specifically, the (A) polyurethane containing a carboxyl group is polyurethane synthesized by using (al) a polyisocyanate compound, (a2) a polyol compound, and (a3) a dihydroxy compound containing a carboxyl group, as monomers. From the viewpoint of a weather resistance and a light resistance, preferably, each of (a1), (a2), and (a3) does not contain a functional group with conjugate properties such as an aromatic compound. Hereinbelow, each monomer will be explained in more detail.

### (a1) Polyisocyanate Compound

For (a1) polyisocyanate compound, usually, diisocyanate which has two isocyanato groups per molecule is used. Examples of the polyisocyanate compound include: aliphatic polyisocyanate, alicyclic polyisocyanate, and the like. One of them may be used by itself, or two or more of them may be used in combination. As far as the polyurethane containing a carboxyl group is not turned into a gel, a small amount of polyisocyanate having three or more isocyanato groups may also be used.

Examples of the aliphatic polyisocyanate include: 1,3-trimethylene diisocyanate, 1,4-tetramethylene diisocyanate, 1,6-hexamethylene diisocyanate, 1,9-nonamethylene diisocyanate, 1,10-decamethylene diisocyanate, 2,2,4-trimethylhexamethylene diisocyanate, 2,4,4-trimethylhexamethylene diisocyanate, lysine diisocyanate, 2,2′-diethyl ether diisocyanate, dimer acid diisocyanate, and the like.

Examples of the alicyclic polyisocyanate include: 1,4-cyclohexane diisocyanate, 1,3-bis (isocyanatomethyl) cyclohexane, 1,4-bis (isocyanatomethyl) cyclohexane, 3-isocyanatomethyl-3,5,5-trimethylcyclohexyl isocyanate (IPDI, isophorone diisocyanate), bis-(4-isocyanato cyclohexyl) methane (Hydrogenated MDI), hydrogenated (1,3- or 1,4-) ylylene diisocyanate, norbornane diisocyanate, and the like.

Here, if an alicyclic compound having 6 to 30 carbon atoms other than the carbon atoms in the isocyanato group (—NCO group) is used as (a1) polyisocyanate compound, a protection layer having a high reliability under high temperature and high humidity, and being suitable as a member for an electronic device component, can be obtained. Among the exemplified alicyclic compounds, 1,4-cyclohexane diisocyanate, isophorone diisocyanate, bis-(4-isocyanato cyclohexyl) methane, 1,3-bis (isocyanatomethyl) cyclohexane, 1,4-bis (isocyanatomethyl) cyclohexane, are preferable.

As mentioned above, from the viewpoints of weather resistance and light resistance, as for (a1) polyisocyanate compound, using a compound which does not have an aromatic ring is preferable. Therefore, when the aromatic polyisocyanate or the aromatic-aliphatic polyisocyanate is used, in accordance with needs, the content thereof is preferably 50 mol% or less, more preferably 30 mol % or less, and still more preferably 10 mol % or less, relative to the total amount (100 mol %) of (a1) polyisocyanate compound.

### (a2) Polyol Compound

The number average molecular weight of (a2) polyol compound (with the proviso that (a2) polyol compound does not include (a3) dihydroxy compound having a carboxyl group, mentioned below) is usually 250 to 50, 000, preferably 400 to 10,000, and more preferably 500 to 5,000. The number average molecular weight of the polyol compound is a polystyrene equivalent value measured by the GPC under the above-mentioned conditions.

Examples of (a2) polyol compound include: polycarbonate polyol, polyether polyol, polyester polyol, polylactone polyol, polysilicone having hydroxyl groups at both ends, and a polyol compound having 18 to 72 carbon atoms obtained by adding hydrogen to a polycarboxilic acid derived from a C18 (carbon atom number 18) unsaturated fatty acid made from vegetable oil and a polymer thereof, and converting the carboxylic acid into hydroxyl groups. Among them, in view of the balance of the water resistance, the insulation reliability, and the adhesion to a base material, polycarbonate polyol is preferable as (a2) polyol compound.

The polycarbonate polyol can be obtained from diol having 3 to 18 carbon atoms as a raw material, through reaction with carbonate ester or phosgene, and can be represented by, for example, the following structural formula (1):

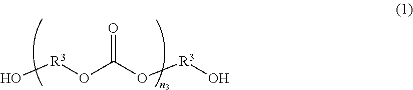

In Formula (1), R³ represents a residue after removing a hydroxyl group from a corresponding diol (HO—R³—OH), i.e., an alkylene group having 3 to 18 carbon atoms, and n₃ represents a positive integer, which is preferably 2 to 50.

Specific examples of the raw material used for producing the polycarbonate polyol represented by Formula (1) include: 1,3-propanediol, 1,4-butanediol, 1,5-pentanediol, 1,6-hexanediol, 3-methyl-1,5-pentanediol, 1,8-octanediol, 1,3-cyclohexanedimethanol, 1,4-cyclohexanedimethanol, 1,9-nonanediol, 2-methyl-1,8-octanediol, 1,10-decamethylene glycol, and 1,2-tetradecanediol, etc.

The polycarbonate polyol may be a polycarbonate polyol (copolymerized polycarbonate polyol) having a plurality of types of alkanediyl groups in its skeleton. Using a copolymerized polycarbonate polyol is advantageous in many cases from the viewpoint of preventing crystallization of (A) polyurethane containing a carboxyl group. Further, taking the solubility to the solvent into account, using, in combination, a polycarbonate polyol having a branched skeleton and having hydroxyl groups at the ends of the branched chains, is preferable.

### (a3) Dihydroxy Compound Containing Carboxyl Group

Preferably, (a3) a dihydroxy compound containing a carboxyl group is a carboxylic acid or an amino carboxylic acid having a molecular weight of 200 or less, having two groups selected from a hydroxy group, a hydroxyalkyl group with one carbon, and a hydroxyalkyl group with 2 carbons, because a cross linking point is controllable. Specific examples include: 2,2-dimethylolpropionic acid, 2,2-dimethylolbutanoic acid, N,N-bis hydroxyethyl glycine, N,N-bis hydroxyethyl alanine, and the like. Among them, in view of the solubility to the solvent, 2,2-dimethylolpropionic acid, 2,2-dimethylolbutanoic acid are particularly preferable. One type of the compounds of (a3) dihydroxy compound containing a carboxyl group can be used by itself, or two or more types may be used in combination.

The above-mentioned (A) a polyurethane containing a carboxyl group can be synthesized from the above three components ((a1), (a2), and (a3)) only. However, (a4) a monohydroxy compound and/or (a5) a monoisocyanate compound may be further reacted for synthesis. In view of the whether resistance and the light resistance, using a compound which does not have an aromatic ring and a carbon-carbon double bond in a molecule is preferable as (a4) a monohydroxy compound and (a5) a monoisocyanate compound.

The (A) polyurethane containing a carboxyl group can be synthesized by reacting the above-mentioned (a1) polyisocyanate compound, (a2) polyol compound, and (a3) dihydroxy compound containing a carboxyl group, under the presence or absence of a known urethanization catalyst such as dibutyltin dilaurate, using an appropriate organic solvent. However, performing reaction of (a1) polyisocyanate compound, (a2) polyol compound, and (a3) dihydroxy compound containing a carboxyl group, without a catalyst is preferable because there would be no need to concern about the mixing of tin, etc., in the final product.

The organic solvent is not particularly limited as far as the reactivity with the isocyanate compound is low, but a preferable solvent is a solvent free from a basic functional group such as amine, etc., and having a boiling point of 50° C. or higher, preferably 80° C. or higher, and more preferably 100° C. or higher. Examples of such a solvent include: toluene, xylylene, ethylbenzene, nitrobenzene, cyclohexane, isophorone, diethylene glycol dimethyl ether, ethylene glycol diethyl ether, ethylene glycol monomethyl ether acetate, propylene glycol monomethyl ether acetate, propylene glycol monoethyl ether acetate, dipropylene glycol monomethyl ether acetate, diethylene glycol monoethyl ether acetate, methoxypropionic acid methyl, methoxypropionic acid ethyl, ethoxypropionic acid methyl, ethoxypropionic acid ethyl, ethyl acetate, n-butyl acetate, isoamyl acetate, ethyl lactate, acetone, methyl ethyl ketone, cyclohexanone, N,N-dimethylformamide, N,N-dimethylacetamide, N-methylpyrrolidone, γ-butyrolactone, dimethyl sulfoxide, and the like.

Taking into account that it is not preferable to use an organic solvent in which the polyurethane to be generated does not dissolve well, and that the polyurethane is used as a raw material for the protection layer ink used for an electronic material, propylene glycol monomethyl ether acetate, propylene glycol monoethyl ether acetate, dipropylene glycol monomethyl ether acetate, diethylene glycol monoethyl ether acetate, γ-butyrolactone, or a combination of some of these, are preferable.

The addition sequence of the raw materials is not limited, but usually, first, (a2) polyol compound and (a3) dihydroxy compound having a carboxyl group are provided in a reaction container, and dissolved or dispersed in the solvent, and thereafter, (a1) polyisocyanate compound is added by dropping at 20 to 150° C., and more preferably at 60 to 120° C., which is then reacted at 30 to 160° C., and more preferably at 50 to 130° C.

The molar ratio of the added raw materials is adjusted in accordance with the molecular weight and the acid value of the objected polyurethane.

Specifically, the molar ratio of the provided materials is that isocyanato group of (a1) polyisocyanate compound: (hydroxyl group of (a2) polyol compound+hydroxyl group of (a3) dihydroxy compound having a carboxyl group) is preferably 0.5 to 1.5:1, more preferably 0.8 to 1.2:1, and still more preferably 0.95 to 1.05:1.

Further, the molar ratio of hydroxyl group of (a2) polyol compound: hydroxyl group of (a3) dihydroxy compound having a carboxyl group is preferably 1:0.1 to 30, and more preferably 1:0.3 to 10.

### (B) Epoxy Compound

Examples of (B) epoxy compound include: an epoxy compound having two or more epoxy groups in one molecule, such as bisphenol-A type epoxy compound, hydrogenated bisphenol-A type epoxy resin, bisphenol-F type epoxy resin, novolak type epoxy resin, phenol novolak type epoxy resin, cresol novolak type epoxy resin, N-glycidyl type epoxy resin, bisphenol A novolak type epoxy resin, chelate type epoxy resin, glyoxal type epoxy resin, amino group-containing epoxy resin, rubber-modified epoxy resin, dicyclopentadiene phenolic type epoxy resin, silicone-modified epoxy resin, ϵ-caprolactone-modified epoxy resin, aliphatic-type epoxy resin containing a glycidyl group, alicyclic epoxy resin containing a glycidyl group, etc.

An epoxy compound having three or more epoxy groups in one molecule is more preferable. Examples of such an epoxy compound include: EHPE (registered trademark) 3150 (manufactured by Daicel Corporation), jER604 (manufactured by Mitsubishi Chemical Corporation), EPICLON EXA-4700 (manufactured by DIC Corporation), EPICLON HP-7200 (manufactured by DIC Corporation), pentaerythritol tetraglycidyl ether, pentaerythritol triglycidyl ether, TEPIC-S (manufactured by Nissan Chemical Corporation), and the like.

The (B) epoxy compound may contain an aromatic ring in a molecule, and in this case, the mass of (B) epoxy compound is preferably 20% by mass or less, relative to the total mass of (A) polyurethane containing a carboxyl group and (B) epoxy compound.

The mixing ratio of (A) polyurethane containing a carboxyl group relative to (B) epoxy compound is preferably 0.5 to 1.5, more preferably 0.7 to 1.3, and still more preferably 0.9 to 1.1, in terms of equivalent ratio of the carboxyl groups of polyurethane relative to the epoxy groups of (B) epoxy compound.

### (C) Curing Accelerator

Examples of (C) curing accelerator include: a phosphine-based compound such as triphenylphosphine, tributylphosphine (manufactured by Hokko Chemical Industry Co., Ltd.), Curezol (registered trademark) (imidazole-based epoxy resin curing agent: manufactured by Shikoku Chemicals Corporation), 2-phenyl-4-methyl-5-hydroxy methyl imidazole, U-CAT (registered trademark) SA series (DBU salt: manufactured by San-Apro Ltd.), Irgacure (registered trademark) 184, and the like. With respect to the used amount of the (C) curing accelerator, if the amount is too small, the effect of addition cannot be obtained, whereas if the amount is too large, the electric insulation is decreased. Therefore, 0.1 to 10% by mass, more preferably 0.5 to 6% by mass, still more preferably 0.5 to 5% by mass, and particularly preferably 0.5 to 3% by mass, is used, relative to the total mass of (A) polyurethane containing a carboxyl group and (B) epoxy compound.

Further, a curing aid may be used together. The curing aid may be a polyfunctional thiol compound, an oxetane compound, and the like. Examples of the polyfunctional thiol compound include: pentaerythritol tetrakis (3-mercaptopropionate), tris-[(3-mercaptopropionyloxy)-ethyl]-isocyanurate, trimethylolpropane tris(3-mercaptopropionate), Karenz (registered trademark) MT series (manufactured by Showa Denko K. K.), and the like. Examples of the oxetane compound include: ARON OXETANE (registered trademark) series (manufactured by Toagosei Co., Ltd.), ETERNACOLL (registered trademark) OXBP or OXMA (manufactured by Ube Industries Ltd.), and the like. The used amount of the curing aid is preferably 0.1 to 10 parts by mass, and more preferably 0.5 to 6 parts by mass, relative to 100 parts by mass of (B) epoxy compound. If 0.1 parts by mass or more is added, the effect of the addition can be sufficiently obtained. If 10 parts by mass or less is added, curing can be performed at a speed suitable for handling.

### (D) Solvent

The content of (D) solvent used in the curable resin composition is preferably 95.0% by mass or more and 99.9% by mass or less, more preferably 96% by mass or more and 99.7% by mass or less, and still more preferably 97% by mass or more and 99.5% by mass or less. For (D) solvent, a solvent which does not damage the transparent conducting layer or the transparent resin film can be used. (D) solvent can be the solvent used for synthesizing (A) polyurethane containing a carboxyl group as it is. Further, other solvent may be used for (D) in order to adjust the solubility of (A) polyurethane containing a carboxyl group or printability. When other solvent is used, the solvent used for synthesizing (A) polyurethane containing a carboxyl group may be distilled away before or after a new solvent is added, to replace the solvent. Taking into account the cumbersomeness of operations and the energy cost, using at least a part of the solvent used for synthesizing (A) polyurethane containing a carboxyl group as it is, is preferable. Taking the stability of the resin composition for the protection layer into account, the solvent has a boiling point of preferably 80° C. to 300° C., and more preferably 80° C. to 250° C. If the boiling point is 80° C. or higher, unevenness caused by too fast drying, can be prevented. If the boiling point is 300° C. or lower, the heat treatment time required for drying and curing can be shortened, which increases the productivity at the time of industrial production.

Examples of the (D) solvent include: a solvent used for synthesizing polyurethane such as propylene glycol monomethyl ether acetate (boiling point 146° C.), γ-butyrolactone (boiling point 204° C.), diethylene glycol monoethyl ether acetate (boiling point)218° C., tripropylene glycol dimethyl ether (boiling point)243° C., etc., an ether-based solvent such as propylene glycol dimethyl ether (boiling point 97° C.), diethylene glycol dimethyl ether (boiling point 162° C.), etc., a solvent having a hydroxyl group such as isopropyl alcohol (boiling point 82° C.), t-butyl alcohol (boiling point 82° C.), 1-hexanol (boiling point) 157° C., propylene glycol monomethyl ether (boiling point 120° C.), diethylene glycol monomethyl ether (boiling point 194° C.), diethylene glycol monoethyl ether (boiling point 196° C.), diethylene glycol monobutyl ether (boiling point 230° C.), triethylene glycol (boiling point 276° C.), ethyl lactate (boiling point 154° C.), etc., methyl ethyl ketone (boiling point 80° C.), and ethyl acetate (boiling point 77° C.). One of these solvents may be used by itself, or a mixture of two or more types of them may be used. When two or more types of solvents are mixed, in addition to the solvent used for synthesizing (A) polyurethane containing a carboxyl group, using a solvent having a hydroxy group and having a boiling point exceeding 100° C. in view of the solubility of (A) polyurethane containing a carboxyl group and (B) epoxy compound, and in order to prevent aggregation or precipitation, or using a solvent having a boiling point of 100° C.or lower in view of the drying property of the curable resin composition, is preferable.

The curable resin composition can be produced by mixing (A) polyurethane containing a carboxyl group, (B) epoxy compound, (C) curing accelerator, and (D) solvent so that the content of (D) solvent becomes 95.0% by mass or more and 99.9% by mass or less, and stirring the mixture until the mixture becomes uniform.

The solid content concentration in the curable resin composition may differ depending on the desired film thickness or printing method, but is preferably 0.1 to 10% by mass, and more preferably 0.5% by mass to 5% by mass. If the solid content concentration is within the range of 0.1 to 10% by mass, when the curable resin composition is coated on a transparent conducting layer, the film thickness cannot be excessively large, and thus, the electrical contact with the transparent conducting layer can be maintained, and in addition, a protection layer having a sufficient weather resistance and light resistance can be obtained.

From the viewpoints of weather resistance and light resistance, the ratio of an aromatic ring-containing compound which is defined by the following formula, in the protection layer (the solid content of (A) polyurethane containing a carboxy group, (B) epoxy compound, and a cured residue of (C) curing accelerator, in the curable resin composition) is preferably suppressed to 15% by mass or less. Here, “cured residue of (C) curing accelerator” refers to (C) curing accelerator remaining in the protection layer under some curing conditions, while all or a part of the (C) curing accelerator may be disappeared (decomposed, vaporized, etc.) depending on the curing conditions. When the amount of (C) curing accelerator remaining in the protection layer after the curing cannot be correctly obtained, it is preferably to calculate the amount based on the charged amount under the presumption that disappearance does not occur under the curing conditions, and use the (C) curing accelerator in a range so that the ratio of the aromatic ring-containing compound becomes 15% by mass or less. Here, the “aromatic ring-containing compound” refers to a compound having at least one aromatic ring in a molecule.

Ratio of aromatic ring-containing compound=[(used amount of aromatic ring-containing compound)/(mass of protection layer (mass of (A) polyurethane containing a carboxy group+mass of (B) epoxy compound+cured residue of (C) curing accelerator)]×100(%)

The above-mentioned curable resin composition is used in a printing method such as a bar-coat printing, gravure printing, ink-jet printing, slit coating, and the like. The curable resin composition is coated on a transparent conducting layer (also referred to as a “metal nanowire layer”), the solvent thereof is dried and removed, and thereafter, the curable resin is cured to form a protection layer. The protection layer obtained after the curing has a thickness exceeding 30 nm and 1 μm or less. The protection layer has a thickness of preferably more than 50 nm and 500 nm or less, and more preferably more than 100 nm and 200 nm or less. If the thickness of the protection layer is 1 μm or less, obtaining conduction with the wiring, in the subsequent process, becomes easy. If the thickness exceeds 30 nm, the effect of protecting the metal nanowire layer can be sufficiently obtained.

The second aspect of the present disclosure is a method for forming a transparent conducting pattern which comprises : a transparent conducting layer forming step for forming a first transparent conducting layer including a binder resin and a nano-structured network having metal nanowire intersections on a first main face of a transparent resin film, and forming a second transparent conducting layer including a binder resin and a nano-structured network having metal nanowire intersections on a second main face of the transparent resin film, respectively; a protection layer forming step for forming a first protection layer on the first transparent conducting layer, and forming a second protection layer on the second transparent conducting layer, respectively; and a pattern forming step for forming a first transparent conducting pattern by etching only the first transparent conducting layer from the first protection layer side using pulse laser having a pulse width shorter than 1 nanosecond, wherein each of the first transparent conducting layer and the second transparent conducting layer has an absorption peak based on the nano-structured network in the optical transmission spectrum, the transparent resin film has a light transmittance of 80% or more in a wavelength region within ±30 nm from the absorption peak maximum wavelength based on the nano-structured network in the optical transmission spectrum and in the visible light region, and has a thickness of 40 μm or more, and the pulse laser has a wavelength within a range of ±30 nm from the absorption peak maximum wavelength based on the nano-structured network in the optical transmission spectrum. The transparent conducting film according to the first aspect can be obtained by a method for forming a transparent conducting pattern according to the second aspect.

In the method for forming a transparent conducting pattern according to the second aspect of the present disclosure, first, a first transparent conducting layer is formed on a first main face of a transparent resin film (which is a substrate), the first transparent conducting layer becoming a base of the first transparent conducting pattern of the transparent conducting film according to the first aspect, and containing a binder resin and a nano-structured network having metal nanowire intersections, and a second transparent conducting layer is formed on a second main face of the transparent resin film (which is the substrate), the second transparent conducting layer becoming a base of the second transparent conducting pattern of the transparent conducting film according to the first aspect, and containing a binder resin and a nano-structured network having metal nanowire intersections, respectively (transparent conducting layer forming step). The method for forming the first transparent conducting layer and the second transparent conducting layer is not limited, but as mentioned above, the layers can be formed by coating a metal nanowire dispersion liquid (metal nanowire ink) on the substrate (transparent resin film), and drying. During the drying and after the drying, performing a treatment such as heating, photoirradiation, etc., is performed to fuse at least a part of the metal nanowire intersections is preferable, from the viewpoint of bending durability. Further, as metal nanowire dispersion liquid (metal nanowire ink), a dispersion liquid without a binder resin may be coated on the substrate and dried to form a nano-structured network having metal nanowire intersections, and thereafter, a solution containing a binder resin may be coated on the nano-structured network having the metal nanowire intersections and dried, to form the first transparent conducting layer and the second transparent conducting layer.

Next, the first protection layer is formed on the first transparent conducting layer, and the second protection layer is formed on the second transparent conducting layer, respectively (protection layer forming step). The protection layer is formed by coating the above-mentioned curable resin composition on the transparent conducting layer by printing, coating, etc., and then, curing. Further, the first protection layer must be formed after the first transparent conducting layer is formed, and the second protection layer must be formed after the second transparent conducting layer is formed. However, it is not necessary to form the first protection layer and the second protection layer after both of the first transparent conducting layer and the second transparent conducting layer are formed. Namely, they can be formed in the order of first transparent conducting layer→second transparent conducting layer→first protection layer→second protection layer, or in the order of first transparent conducting layer→first protection layer→second transparent conducting layer→second protection layer. The structure of the protection layer is the same as the above-mentioned first aspect, and thus, detailed explanation is omitted here.

Subsequently, using pulse laser having a pulse width of shorter than 1 nanosecond, the etching treatment is applied only to the first transparent conducting layer from the first protection layer side, to form the first transparent conducting pattern (pattern forming step). In the optical transmission spectrum, the transparent conducting layer has a characteristic absorption peak based on the nano-structured network having metal nanowire intersections, which constitutes the transparent conducting layer, in the ultraviolet ray region. The inventors of the present disclosure have found out that: when the pulse laser having a wavelength within a wavelength region of ±30 nm from the absorption peak maximum wavelength based on the nano-structured network in the optical transmission spectrum, the light transmittance of the transparent resin film being 80% or more in the wavelength, and having a pulse width of shorter than 1 nanosecond, is applied from the first protection layer side, the second transparent conducting layer is not etched, and only the first transparent conducting layer can be selectively etched. The nano-structured network having the metal nanowire intersections has an absorption peak caused thereby in the ultraviolet ray region of the optical transmission spectrum, and thus, can be etched by a pulse laser having a wavelength close to this absorption peak maximum wavelength (within the range of ±30 nm from the absorption peak maximum wavelength).

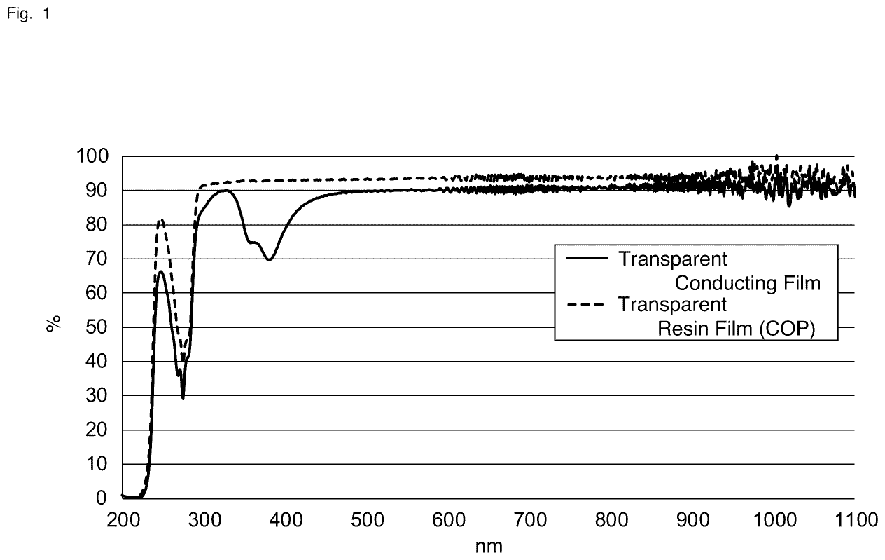

FIG. 1 shows optical transmission spectrum of the transparent conducting film in which the transparent resin film is COP and the metal nanowire is silver nanowire (AgNW) (a transparent conducting film in the step that the first transparent conducting layer and the first protection layer are formed in the same way as the following Coating Example 1), and the optical transmission spectrum of COP (ZF14-100, thickness 100 μm, manufactured by Zeon Corporation) only. In FIG. 1, the lateral axis represents a wavelength, and the vertical axis represents a light transmittance (%).

As shown in FIG. 1, the nano-structured network having the silver nanowire intersections, has an absorption peak having a local maximum at a wavelength of 380 nm. This derives from a nano-structured network based on silver nanowires. If an ultraviolet-visible spectrum of the silver nanowire is measured under the state that the silver nanowires are dispersed in a liquid, a peak having a local maximum at a wavelength region of 365 to 370 nm can be found, although depending on the diameter of the silver nanowire. The precise reason why the absorption peak maximum wavelength is shifted to the longer wavelength side, but it is assumed that there is an influence from the fact that the silver nanowires are fused with each other.

Regarding the transparent resin film itself, which is a substrate in the transparent conducting film, having a high transmittance in a wide wavelength region is preferable, and thus, in the optical transmission spectrum, having a high light transmittance (80% or more) is required even in a wavelength region near the absorption peak maximum wavelength derived from the nano-structured network. The inventors have found out that: when such a transparent resin film is used, a pulse laser having a pulse width of shorter than 1 nanosecond can progress in the transparent resin film to some extent, but cannot penetrate the transparent resin film if the film has a thickness of 40 μm or more, and even if the pulse laser can penetrate the transparent resin film, the second transparent conducting layer cannot be etched to the extent of losing conductivity. If the transparent resin film has a thickness of less than 40 μm, there are drawbacks that the pulse laser penetrates (transmits) the transparent resin film, and the laser ray reaches and etches the second transparent conducting layer which should not be etched.

After the above-mentioned selective etching treatment of the first transparent conducting layer from the first protection layer side, similarly, a selective etching treatment of the second transparent conducting layer from the second protection layer can be performed. Namely, regarding the second transparent conducting layer, a second transparent conducting pattern layer having a second conducting region and a second non-conducting region, which is different from the first transparent conducting pattern layer formed on the first transparent conducting layer and having the first conducting region and the first non-conducting region, can be formed. As mentioned above, the second transparent conducting pattern layer can be left as a solid-patterned transparent conducting layer, without applying the etching treatment. The pulse laser has a pulse width of preferably less than 0.1 nanosecond (100 picoseconds), more preferably less than 0.01 nanosecond (10 picoseconds), and still more preferably less than 0.001 nanosecond (1 picosecond), that is, using femtosecond pulse laser.

When the transparent conducting layer is etched with the above-mentioned pulse laser (the non-conducting region is formed), the metal which forms the nano-structured network having the metal nanowire intersections constituting the transparent conducting layer and which is located in the range that has become the non-conducting region by the pulse laser irradiation, is melted. Thus, a network structure sufficient to obtain conductivity cannot be maintained. The wire-shaped metal forming the nano-structured network is broken, and the non-conducting region contains fragments of the nano-structured network. The fragments have various shapes. For example, the segment may have a particle shape (spherical, ellipsoidal, columnar, etc.) formed by breaking the metal nanowire. The segment may be the one formed by finely breaking the metal nanowire to the extent that the non-conducting region as a whole becomes non-conductive although the network structure (including metal nanowire intersections) partly remains (such as an intersection of the metal nanowire (such as a cross-shaped segment)), etc. Completely removing the segments of the nano-structured network generated in the non-conducting region by the etching process is possible. However, if the segments are completely removed, the contrast between the conducting region and the non-conducting region becomes high, and thus, the visibility becomes lowered (pattern visibility easily occurs). Therefore, preferably, all the segments should not be removed.

### EXAMLES

Hereinbelow, specific examples of the present disclosure will be specifically explained. The examples are described below for the purpose of easy understanding of the present disclosure, and the present disclosure is not limited to these examples.

### Coating Example 1

### <Preparation of Transparent Conducting Film>

### <Synthesis of Silver Nanowire>

100 g of propylene glycol (manufactured by FUJIFILM Wako Pure Chemical Corporation) was weight in a 200 mL glass container, and 2.3 g (13 mmol) of silver nitrate (manufactured by Toyo Chemical Industrial Co., Ltd.) as a metal salt was added thereto, which was stirred for 2 hours at a room temperature, to thereby prepare a silver nitrate solution (Second Solution).

600 g of propylene glycol, 0.052 g (0.32 mmol) of tetramethylammonium chloride (manufactured by Lion Specialty Chemicals Co., Ltd.), 0.008 g (0.08 mmol) of sodium bromide (manufactured by Manac Inc.), and 7.2 g of polyvinylpyrrolidone K-90 (PVP) (weight average molecular weight: 350, 000, manufactured by FUJIFILM Wako Pure Chemical Corporation) as a structure-directing agent were provided in a 1 L four-neck flask (mechanical stirrer, dropping funnel, reflux tube, thermometer, nitrogen gas introducing tube) under the nitrogen gas atmosphere, which was stirred for 1 hour at a rotation speed of 200 rpm, and at 150° C. until complete dissolution, and thereby, First Solution was obtained. The previously prepared silver nitrate solution (Second Solution) was provided in the dropping funnel, and dropped into First Solution for 2.5 hours, at a temperature of 150° C.(supply molar number of the silver nitrate: 0.087 mmol/min), to thereby synthesize silver nanowires. After the dropping was complete, heating and stirring was continued for 1 hour, to complete the reaction.

### <Cross-Flow Filtration of Silver Nanowire Dispersion Liquid>

The obtained silver nanowire coarse dispersion liquid was dispersed in 2000 ml of water, which was poured into a desktop small tester (using ceramic membrane filter Cefilt, membrane area: 0.24 m², pore size: 2.0 μm, size Φ: 30 mm×250 mm, filtration differential pressure: 0.01 MPa, manufactured by NGK Insulators, Ltd.), and was subjected to cross-flow filtration at a circulation flow rate of 12 L/min and a dispersion liquid temperature of 25° C., to remove impurities. Thereby, silver nanowires (average diameter: 26 nm, average length: 20 μm) were obtained. During the cross-flow filtration, the water/ethanol displacement was performed, and finally, a dispersion liquid of a water/ethanol mixed solvent (silver nanowire concentration: 3% by mass, water/ethanol=41/56 [mass ratio]) was obtained. The average diameter of the obtained silver nanowires was obtained by using Field Emission Scanning Electron Microscope JSM-7000F (manufactured by JEOL Ltd.). Sizes (diameters) of arbitrarily selected 100 silver nanowires were measured, and the arithmetic average value thereof was calculated. The average length of the obtained silver nanowires was obtained by using Shape Measurement Laser Microscope VK-X200 (manufactured by Keyence Corporation). Sizes (lengths) of arbitrarily selected 100 silver nanowires were measured, and the arithmetic average value thereof was calculated.

### <Preparation of Metal Nanowire Ink (Silver Nanowire Ink)>

5 g of dispersion liquid of silver nanowires synthesized by the above polyol method in a water/ethanol mixture solvent (silver nanowire concentration: 3% by mass, water/ethanol=41/56 [mass ratio]), 6.4 g of water, 20 g of methanol (manufactured by FUJIFILM Wako Pure Chemical Corporation), 39 g of ethanol (manufactured by FUJIFILM Wako Pure Chemical Corporation), 25 g of propyleneglycol monomethyl ether (PGME, manufactured by FUJIFILM Wako Pure Chemical Corporation), 3 g of propylene glycol (PG, manufactured by AGC Inc.), and 1.8 g of PNVA (registered trademark) aqueous solution (solid content concentration: 10% by mass, weight-average molecular weight: 900,000, manufactured by Showa Denko K. K.) were mixed and stirred by Mix Rotor VMR-5R (manufactured by AS ONE Corporation) for 1 hour, at a room temperature and under an air atmosphere (rotation speed: 100 rpm), to thereby produce 100 g of silver nanowire ink. The final mixture ratio was silver nanowire/PNVA/water/methanol/ethanol/PGME/PG=0.15/0.18/10/20/42/25/3.

The concentration of silver nanowire contained in the obtained silver nanowire ink was measured by AA280Z Zeeman atomic absorption spectrophotometer, manufactured by Varian.

### <Formation of Transparent Conducting Layer (Silver Nanowire Layer)>

Using Corona Discharge Surface Treatment System for A4-size, A4SW-FLNW (manufactured by Wedge Co., Ltd.), corona discharge treatment (conveyance speed: 3 m/min, treatment times: twice, output: 0.3 kW) was applied to both of the main faces of a cyclo olefin polymer (COP) film ZF14-100 (thickness 100 μm, manufactured by Zeon Corporation) of A4 size, used as a substrate. Using the COP film subjected to the corona discharge treatment, TQC Automatic Film Applicator Standard (manufactured by Kotec Ltd.), and Wireless Bar Coater OSP-CN-22L (manufactured by Kotec Ltd.), a silver nanowire ink was coated on the entire surface of the first main face of the COP film (coating speed 500 mm/sec) to have a wet film thickness of 22 μm. Thereafter, the coated film was subjected to hot-air drying at 80° C., for 3 minutes, and under an air atmosphere, by using a constant temperature oven HISPEC HS350 (manufactured by Kusumoto Chemicals Ltd.), and thereby a first transparent conducting layer (silver nanowire layer) was formed.

### <Film Thickness Measurement>

Film thickness of the transparent conducting layer (silver nanowire layer) was measured using a film thickness measurement system F20-UV (manufactured by Filmetrics Japan, Inc.). Measurement was performed at three different points, and an average value of the measurement results of the three points was used as a film thickness. For analysis, spectrum of 450 nm to 800 nm was used. According to this measurement system, the film thickness (T_{c}) of the transparent conducting layer (silver nanowire layer) formed on the transparent substrate can be directly measured. Table 1 shows the measurement results.

### <Preparation of Curable Resin Composition 1>

(A) Polyurethane Containing Carboxyl Group Synthesis Example

42.32 g of C-1015N (polycarbonate diol, molar ratio of raw material diols: 1,9-nonanediol: 2-methyl-1,8-octanediol=15:85, molecular weight: 964, manufactured by Kuraray Co., Ltd.) as (a2) polyol compound, 27.32 g of 2,2-dimethylol butanoic acid (manufactured by Nihon Kasei K. K.) as (a3) dihydroxy compound containing a carboxy group, and 158 g of diethylene glycol monoethyl ether acetate (manufactured by Daicel Corporation) as a solvent were provided in a 2 L three-neck flask having a stirrer, a thermometer, and a condenser, and the 2,2-dimethylol butanoic acid was dissolved at 90° C.

The temperature of the reaction liquid was lowered to 70° C., and 59.69 g of Desmodur (registered trademark)-W (bis (4-isocyanatocyclohexyl) methane), manufactured by Sumika Covestro Urethane Co., Ltd.), as (a1) polyisocyanate compound, was dropped thereto for 30 minutes by a dropping funnel. After the dropping was complete, the temperature was raised to 120° C., and the reaction was performed at 120° C. for 6 hours. After the confirmation by IR that almost all of the isocyanate disappeared, 0.5 g of isobutanol was added, which was further reacted at 120° C. for 6 hours. The obtained (A) carboxy group-containing polyurethane had a weight average molecular weight, obtained by GPC, of 32300, and (A) carboxy group-containing polyurethan had an acid value of 35.8 mgKOH/g.

10.0 g of the above obtained solution of (A) polyurethane containing a carboxy group (content of polyurethane containing a carboxy group: 45% by mass) was weighed in a polyethylene container, and 85.3 g of 1-hexanol and 85.2 g of ethyl acetate as (D) solvent were added thereto, which was stirred by Mix Rotor VMR-5R (manufactured by AS ONE Corporation) for 12 hours, at a room temperature and under an air atmosphere (rotation speed: 100 rpm). When the mixture was visually confirmed as being uniform, 0.63 g of pentaerythritol tetraglycidyl ether (manufactured by Showa Denko K. K.) as (B) epoxy compound and 0.31 g of U-CAT5003 (compound name: benzyltriphenylphosphonium bromide, manufactured by San-Apro Ltd.) as (C) curing accelerator, were added thereto, which were stirred again by Mix Rotor for 1 hour. Thereby, a curable resin composition 1 was obtained.

### <Formation of Protection Layer (Overcoat Layer) >

The curable resin composition 1 was coated on the entire surface of the silver nanowire layer (first transparent conducting layer) formed on the first main face of the transparent resin film (COP film ZF14-100 (thickness 100 μm, manufactured by Zeon Corporation)), which is a substrate, by using TQC Automatic Film Applicator Standard (manufactured by COTEC Corporation) and Wireless Bar Coater OSP-CN-05M (manufactured by COTEC Corporation) to have a wet film thickness of 5 μm (coating speed: 333 mm/sec), which was thereafter subjected to hot-air drying (thermosetting) at 80° C., for 1 minute, and under an air atmosphere, by using a constant temperature oven HISPEC HS350 (manufactured by Kusumoto Chemicals Ltd.), and thereby a first protection layer was formed.

After the protection layer was formed on the first main face, a second transparent conducting layer (silver nanowire layer) and a second protection layer were sequentially formed on the second main face of the COP film, in the same way as above. Thereby, a transparent conducting film having a conducting layer on each of the main faces was produced.

### <Confirming Fusion of Metal Nanowire (Silver Nanowire) Intersections>

In order to confirm the state of fusion at metal nanowire (silver nanowire) intersections, the COP film before the protection layer was formed, that is, the COP film on which the silver nanowire (AgNW) layer was coated, was subjected to vapor deposition with a carbon rod for 5 seconds at a current value of 50 A, by using a vacuum vapor deposition device VE-2030 manufactured by K. K. Vacuum Device. Thereby, a carbon protection layer was formed directly on the nanowires. Next, using FIB (Focused ion beam) processing machine FB-2100 (acceleration voltage: 40 kV), an intersection at which AgNW and AgNW intersects at an angle of close to 90° is confirmed, and a linear marking is provided on an extended line of the AgNW including the intersection as a guide mark for the AgNW.

Next, the above carbon vapor deposition device was used again for 10 seconds to form an additional carbon protection layer, and thus, a carbon layer of approximately 80 nm in total was formed under the state that the marking can be recognized. Thereby, the AgNW was protected from the damage due to the FIB processing, and the nanowires were prevented from being interfered by the upper protection layer at the time of observation by TEM.

Then, in accordance with the above marking, tungsten deposition using the above FIB processing machine was performed for 10 minutes, to thereby form a tungsten protection layer having 12 μm in the major axis direction of AgNW, 2 μm in the direction perpendicular to the major axis of AgNW, and 1 μm in thickness. The portion encompassing the tungsten protection layer was scraped by the FIB to the depth of approximately 15 μm, and the layer under the tungsten protection layer and including the AgNW intersection was cut out, which was fixed to copper mesh, and made into a thin piece under the condition of current value 0.01 nA, to thereby form a thin piece including the AgNW intersection and having a thickness of approximately 100 nm.

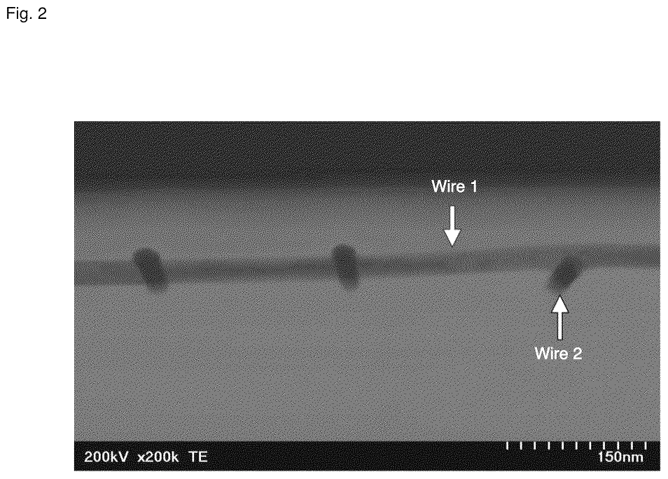

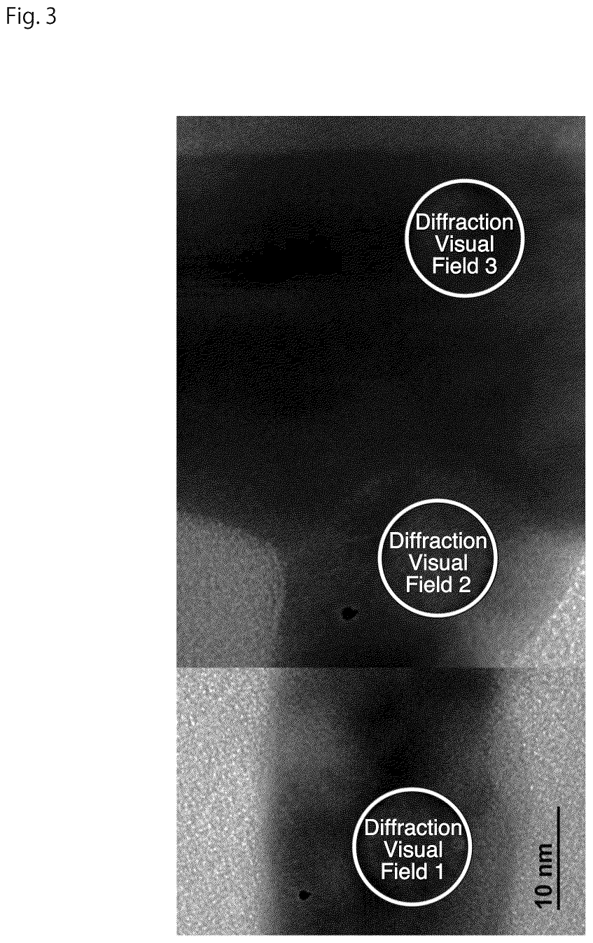

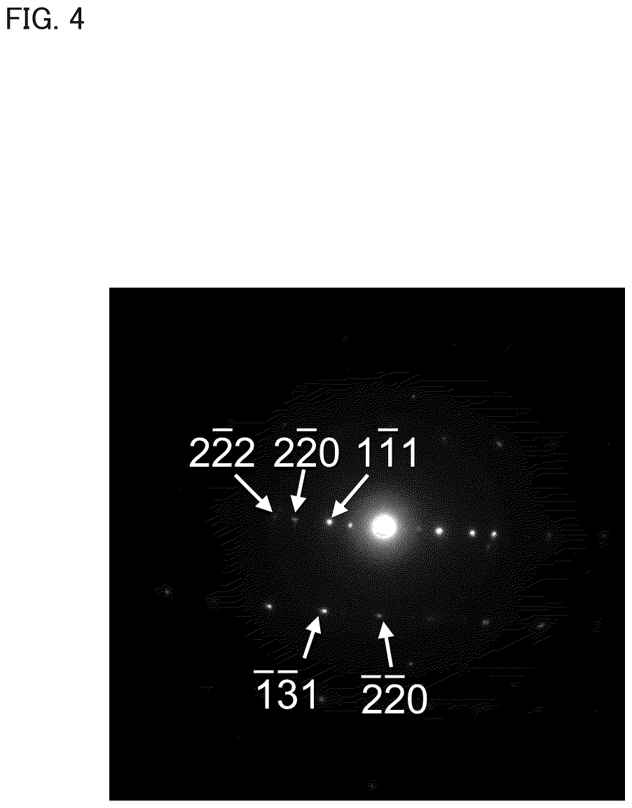

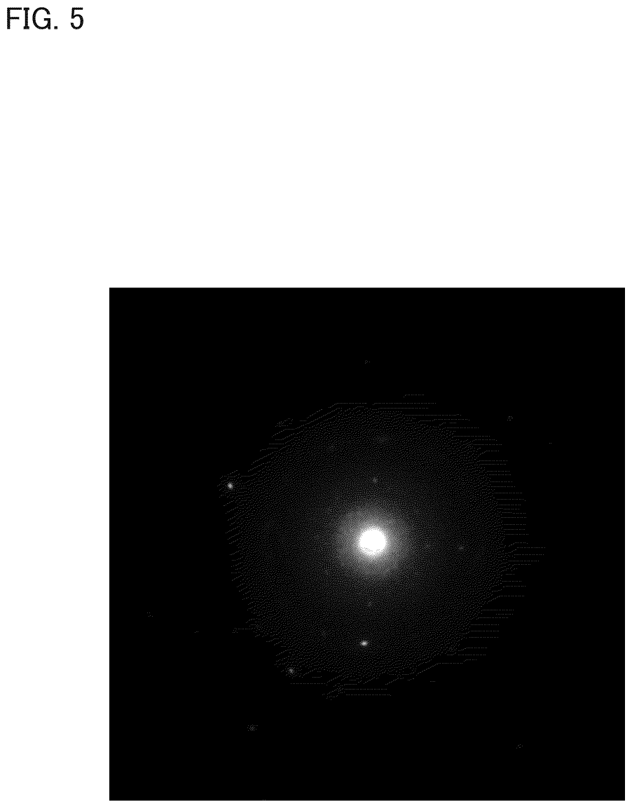

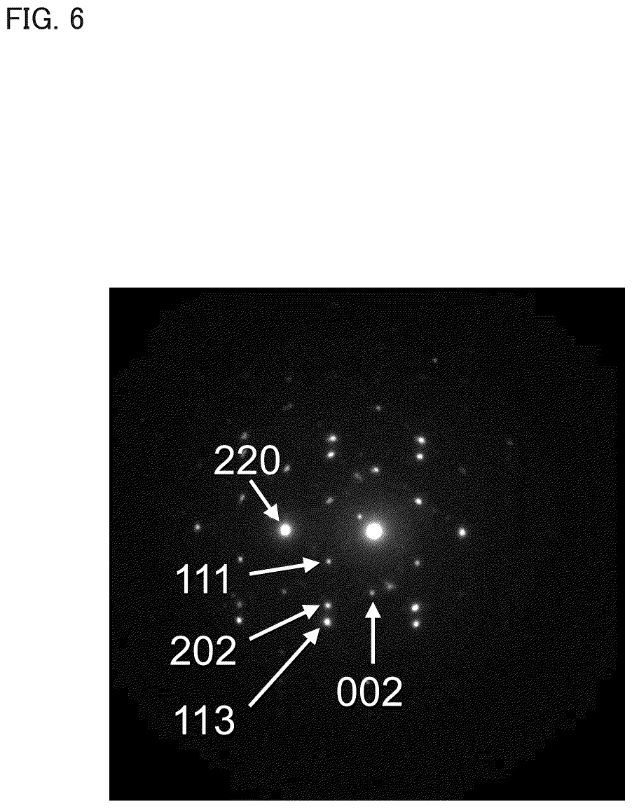

Using a transmission electron microscope (TEM) HF-2200 (acceleration voltage: 200 kV) manufactured by Hitachi High-Tech Corporation, the thin piece sample was observed. The observation revealed that one AgNW was contained in the sample in the right-left direction, and there were many intersections between the one AgNW and other AgNWs extending from the back to the front. At the intersection, the boundary between the AgNW extending in the right-left direction (Wire 1) and the AgNW extending from the back to the front (Wire 2) was unclear, which suggested that they were fused (FIG. 2). When the crystal structure of the AgNW around the intersection was observed by electron-beam diffraction at the camera length of 0.15 m, a typical diffraction pattern in which a pentagonal crystal twinning structure, peculiar to the AgNW, of Wire 2 was reflected, and 1-11, 2-22, -1-31, -2-20 diffractions corresponding to the crystal zone axis [112], and 2-20 diffraction corresponding to the crystal zone axis were superimposed (FIG. 4), was exhibited, at a position sufficiently depart from the intersection (FIG. 3, diffraction visual field 1). On the other hand, when the crystal structure was observed at a position close to the area including the intersection (FIG. 3, diffraction visual field 2), the typical diffraction pattern disappeared from the electron-beam diffraction of Wire 2 (FIG. 5). From the above, it was believed that Wire 2 was melted at the relevant portion, and thereafter, recrystallized to largely change the orientation. At the intersection of Wire 1 and Wire 2 (FIG. 3, diffraction visual field 3), the typical diffraction pattern in which a pentagonal crystal twinning structure of Wire 1 was reflected, and 002, 111, 220, 113 diffractions corresponding to the crystal zone axis [110], and 202 diffraction corresponding to the crystal zone axis were superimposed, was remarkably exhibited (FIG. 6). The above-mentioned electron-beam diffraction revealed that regarding Wire 2, the pentagonal crystal twinning structure was melted near the intersection with Wire 1, and the portion was recrystallized around the pentagonal prism of Wire 1 as a crystal having a completely different orientation, that is to say, the portion was fused.

### Coating Example 2

Except that a cyclo olefin polymer (COP) film ZF14-050 (thickness 50 μm, manufactured by Zeon Corporation) was used as a substrate for producing the transparent conducting film, the process was the same as Coating Example 1.

### Coating Example 3

Except that a cyclo olefin polymer (COP) film ZF16-040 (thickness 40 μm, manufactured by Zeon Corporation) was used as a substrate for producing the transparent conducting film, and that OSP-CN-07M (wet film thickness 7 μm, manufactured by COTEC Corporation) was used as a wireless bar-coater used for forming the protection layer, the process was the same as Coating Example 1.

### Coating Example 4

Except that that a polycarbonate film FS2000H (thickness 100 μm, manufactured by Mitsubishi Gas Chemical Company, Inc.) was used as a substrate for producing the transparent conducting film, and that the corona treatment applied to both main faces before the formation of the silver nanowire layers was omitted, the process was the same as Coating Example 3.

### Coating Example 5

Except that a polycarbonate film FS2000HJ (thickness 50 μm, manufactured by Mitsubishi Gas Chemical Company, Inc.) was used as a substrate for producing the transparent conducting film, the process was the same as Coating Example 4.

### Coating Comparative Example 1

Except that a cyclo olefin polymer (COP) film ZF14-023 (thickness 23 μm, manufactured by Zeon Corporation) was used as a substrate for producing the transparent conducting film, the process was the same as Coating Example 1.

### Coating Comparative Example 2

Except that a cyclo olefin polymer (COP) film ZF14-013 (thickness 13 μm, manufactured by Zeon Corporation) was used as a substrate for producing the transparent conducting film, the process was the same as Coating Example 1.

<Measurement of Transmittance in Wavelength Region of ±30 nm from Absorption Peak Maximum Wavelength>

Each transparent resin film, i.e., substrate, was cut to have a test piece of 3 cm*3 cm. The optical transmission spectrum of the test piece in the wavelength 200 nm to 1100 nm was measured by UV-visible spectrophotometer UV-2400PC (manufactured by Shimadzu Corporation), and thereafter, the transmittance in the wavelength region of ±30 nm relative to the absorption peak maximum wavelength measured as below, was calculated.

### <Sheet Resistance Measurement of Silver Nanowire Layer>

A 3 cm*3 cm test piece was cut out from the transparent conducting film (silver nanowire film) having a silver nanowire layer and a protection layer formed, in this order, on each of the main faces of the transparent resin film, and sheet resistances of the silver nanowire layers formed on the respective main faces were respectively measured by 4-probe Resistivity Meter Loresta GP (manufactured by Mitsubishi Chemical Analytech Co., Ltd.). The measurement mode and the used probe were ESP mode.

### <Absorption Peak Maximum Wavelength Measurement of Nano-Structured Network>

Using a 3 cm*3 cm test piece of the transparent conducting film (silver nanowire film) having a silver nanowire layer and a protection layer formed, in this order, on each of the main faces of the transparent resin film, and UV-visible spectrophotometer UV-2400PC (manufactured by Shimadzu Corporation), a transmittance (absorption) spectrum in the region having a wavelength of 200-1100 nm was measured, and an absorption peak maximum wavelength value of the nano-structured network was obtained from the spectrum. Here, it was confirmed that the protection layer was thin, and the protection layer by itself did not exhibit characteristic absorption in the UV region and the visible region.

<Measurement of transmittance (Total Light Transmittance) at Wavelength of 400 to 700 nm and Measurement of Haze>

Using a 3 cm*3 cm test piece of the transparent conducting film (silver nanowire film) having a silver nanowire layer and a protection layer formed, in this order, on each of the main faces of the transparent resin film, measurement was performed by Haze meter COH7700 (manufactured by Nippon Denshoku Industries Co., Ltd.). The total light transmittance was measured based on JIS K 7361-1, and the haze was measured based on JIS K 7136. The measurement results are shown in Table 1. Similarly, the transmittance (total light transmittance) at the wavelength of 400 to 700 nm of the transparent resin film only was also measured.

### <Film Thickness of Protection Layer>

A thickness of the protection layer was measured using a film thickness measurement system F20-UV (manufactured by Filmetrics Japan, Inc.) based on optical interferometry, in the same way as the thickness measurement of the silver nanowire layer. Measurement was performed at three different points, and an average value of the measurement results of the three points was used as a film thickness. For analysis, spectrum of 450 nm to 800 nm was used. According to this measurement system, the total layer thickness (T_{c}+Tₚ) can be directly measured, the layer thickness (T_{c}) being a thickness of the silver nanowire layer formed on the transparent substrate, and the layer thickness (Tₚ) being a thickness of the protection layer formed on the silver nanowire layer. Thus, by subtracting the previously measured layer thickness (T_{c}) of the silver nanowire layer from this measurement value (T_{c}+Tₚ), the layer thickness (Tₚ) of the protection layer can be obtained. The measurement results are shown in Table 1.

TABLE 1

| | | | | | | | | Coating | Coating |
|---|---|---|---|---|---|---|---|---|---|
| | | | Coating | Coating | Coating | Coating | Coating | Comp. | Comp. |
| | | Unit | Ex. 1 | Ex. 2 | Ex. 3 | Ex. 4 | Ex. 5 | Ex. 1 | Ex. 2 |
| Physical | Resin Type | — | COP | COP | COP | PC | PC | COP | COP |
| Property | Model No. | — | ZF14-100 | ZF14-050 | ZF16-040 | FS-2000H | FS-2000HJ | ZF14-023 | ZF14-013 |
| Values of | Substrate Thickness | μm | 100 | 50 | 40 | 100 | 50 | 23 | 13 |
| Transparent | Transmittance in wavelength region | % | 80≤ | 80≤ | 80≤ | 80≤ | 80≤ | 80≤ | 80≤ |
| Resin Film | within ±30 nm from absorption peak | | | | | | | | |
| | maximum wavelength | | | | | | | | |
| | Transmittance in wavelength 400-700 | % | 91.3 | 91.3 | 91.3 | 90.0 | 90.1 | 91.3 | 91.3 |
| | nm (total light transmittance) | | | | | | | | |
| Physical | Sheet Resistance (1st Face) | Ω/□ | 50 | 50 | 50 | 50 | 50 | 50 | 50 |
| Property | Sheet Resistance (2nd Face) | Ω/□ | 50 | 50 | 50 | 50 | 50 | 50 | 50 |
| Values of | Absorption peak maximum wavelength | nm | 380 | 380 | 380 | 380 | 380 | 380 | 380 |
| Transparent | based on nano-structured network | | | | | | | | |
| Conducting | Transmittance in wavelength 400-700 | % | 89.5 | 89.5 | 89.5 | 89.0 | 89.0 | 89.5 | 89.5 |
| Film | nm (total light transmittance) | | | | | | | | |
| | Haze | % | 1.4 | 1.1 | 1.4 | 1.4 | 1.2 | 1.4 | 1.4 |
| | Silver Nanowire Layer Thickness | nm | 80 | 80 | 80 | 80 | 80 | 80 | 80 |
| | (1st Face) T_{C1} | | | | | | | | |
| | Protection Layer Thickness | nm | 90 | 90 | 100 | 100 | 100 | 90 | 90 |
| | (1st Face) T_{P1} | | | | | | | | |
| | Silver Nanowire Layer Thickness | nm | 80 | 80 | 80 | 80 | 80 | 80 | 80 |
| | (2nd Face) T_{C2} | | | | | | | | |
| | Protection Layer Thickness | nm | 90 | 90 | 100 | 100 | 100 | 90 | 90 |
| | (2nd Face) T_{P2} | | | | | | | | |

### Example 1

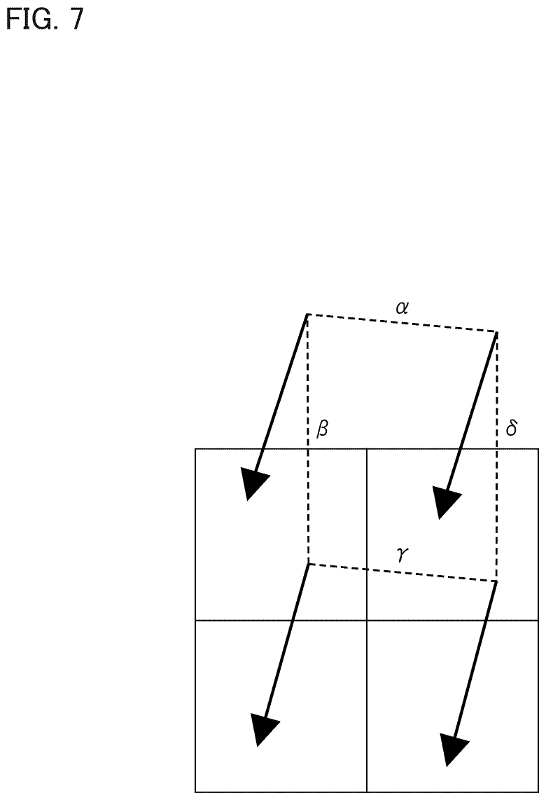

Pattern processing was applied to the first face of the transparent conducting film produced in accordance with Coating Example 1, by a femtosecond pulse laser (pulse width 500 fs (500*10⁻⁶ ns), frequency 1000 kHz, processing speed 5000 mm/s, output 0.2 W) with a wavelength of 355 nm. The drawn pattern was a lattice pattern with 2-cm grid spacing, as shown in FIG. 7. Probes of a digital multimeter PC5000a (manufactured by Sanwa Electric Instrument Co., Ltd.) were applied to step across the four lines located inside of the lattice. FIG. 7 shows the pattern and how the probes were applied. In FIG. 7, the solid line representing the lattice is an etching line formed by the pattern processing, and the arrows represent probes. Further, α, β, γ, δ represent that apexes of two arrows (probes) connected by a corresponding broken line are applied to the inside of the lattice (a region which is not etched), and resistance value between the two regions divided by the etching line is measured.

The case that no numeral values (resistance values) are obtained in all of the probe applications α, β, γ, δ (between two regions), is evaluated as “non-conductive (=etching is sufficient)”. The case that a numeral value is obtained in at least one of α to δ, is evaluated as “conductive (=etching is insufficient)”. The evaluation results of the processed faces (front faces) are shown in Table 2.

Subsequently, the film was turned over, and the probes of the digital multimeter were applied to step over the etching line on the pattern-processed face. The case that numeral values are obtained in all of α to δ, is evaluated as “conductive (=rear face is not processed)”. The case that no numeral value is obtained in at least one of α to δ, is evaluated as “non-conductive (=rear face is at least partly processed)”. The evaluation results of the rear faces are also shown in Table 2.

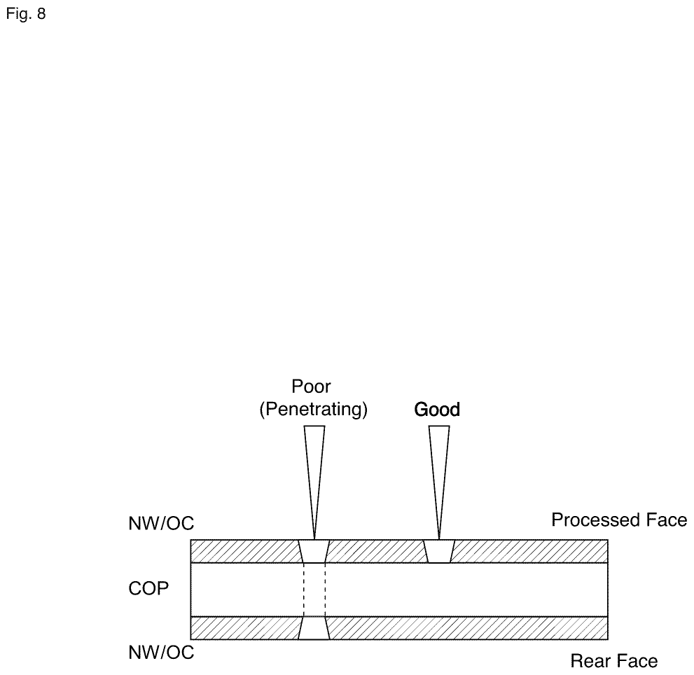

As comprehensive evaluation, the case satisfying both the processed face (front face) being “non-conductive”, and the rear face being “conductive” is determined as Good, and others are determined as Poor. FIG. 8 shows an image how Good and Poor are determined in the comprehensive evaluation. FIG. 8 shows the case that pulse laser is irradiated from the processed face side to perform etching, and no pulse laser is irradiated from the rear face side. In FIG. 8, the case that the pulse laser does not penetrates to the rear face side and the “conductive” state is maintained on the rear face, is evaluated as Good; whereas, the case that the pulse laser penetrates to the rear face and the “conductive” state is not maintained in the rear face, is evaluated as Poor.

### Example 2

Except that the transparent conducting film to be etched is changed to the film according to Coating Example 2, measurement and evaluation were performed in the same as Example 1.

### Example 3

Except that the transparent conducting film to be etched is changed to the film according to Coating Example 3, measurement and evaluation were performed in the same as Example 1.

### Example 4

Except that the transparent conducting film to be etched is changed to the film according to Coating Example 4, measurement and evaluation were performed in the same as Example 1.

### Example 5

Except that the transparent conducting film to be etched is changed to the film according to Coating Example 5, measurement and evaluation were performed in the same as Example 1.

### Comparative Example 1

Except that the transparent conducting film to be etched is changed to the film according to Coating Comparative Example 1, measurement and evaluation were performed in the same as Example 1.

### Comparative Example 2

Except that the transparent conducting film to be etched is changed to the film according to Coating Comparative Example 2, measurement and evaluation were performed in the same as Example 1.

### Comparative Example 3

Except that the laser used for the etching was changed to the nanosecond pulse laser (pulse width 180 ns, frequency: 90 kHz, processing speed 500 mm/s, output 0.2 W), measurement and evaluation were performed in the same as Example 1.

### Comparative Example 4

Except that the laser used for the etching was changed to the picosecond pulse laser (pulse width 50 ps (50*10⁻³ ns), frequency: 90 kHz, processing speed 500 mm/s, output 0.2 W) with a wavelength of 1064 nm, measurement and evaluation were performed in the same as Example 1.

TABLE 2

| | | | | | | | | | | | | Comparative | | Comparative | | Comparative | | Comparative | |
|---|---|---|---|---|---|---|---|---|---|---|---|---|---|---|---|---|---|---|---|
| | | Example 1 | | Example 2 | | Example 3 | | Example 4 | | Example 5 | | Example 1 | | Example 2 | | Example 3 | | Example 4 | |
| Transparent | | Coating | | Coating | | Coating | | Coating | | Coating | | Coating | | Coating | | Coating | | Coating | |
| Conducting Film | | Example 1 | | Example 2 | | Example 3 | | Example 4 | | Example 5 | | Comparative | | Comparative | | Example 1 | | Example 1 | |
| | | | | | | | | | | | | Example 1 | | Example 2 | | | | | |
| Laser | Wavelength | 355 | nm | 355 | nm | 355 | nm | 355 | nm | 355 | nm | 355 | nm | 355 | nm | 355 | nm | 1064 | nm |
| Processing | Pulse Width | 500 | fs | 500 | fs | 500 | fs | 500 | fs | 500 | fs | 500 | fs | 500 | fs | 180 | ns | 50 | ps |
| Conditions | | | | | | | | | | | | | | | | | | | |

| | | | | | | | | | | |
|---|---|---|---|---|---|---|---|---|---|---|
| Laser | Processed | Non-Con- | Non-Con- | Non-Con- | Non-Con- | Non-Con- | Non-Con- | Non-Con- | Non-Con- | Non-Con- |
| Processing | Face | ductive | ductive | ductive | ductive | ductive | ductive | ductive | ductive | ductive |
| Results | (Front Face) | | | | | | | | | |
| | Rear Face | Con- | Con- | Con- | Con- | Con- | Non-Con- | Non-Con- | Non-Con- | Non-Con- |
| | | ductive | ductive | ductive | ductive | ductive | ductive | ductive | ductive | ductive |
| | Comprehensive | Good | Good | Good | Good | Good | Poor | Poor | Poor | Poor |
| | Evaluation | | | | | | | | | |

As is apparent from the comparison between Examples 1 to 5 and Comparative Examples 1, 2, by using the transparent conducting film and the processing method according to the present disclosure, a transparent conducting layer on one of the main faces can be selectively subjected to the laser etching processing. Further, as is apparent from the comparison between Example 1 and Comparative Example 3, even if the film according to the same Coating Example is used and processed at the same laser wavelength, the etching (patterning) can be succeeded/failed depending on the pulse width. Namely, according to the method disclosed in Patent Document 2, wherein only the substrate thickness (resin type) and the laser wavelength are designated, a desired processing (processing that the laser does not penetrate to the rear face) cannot be always achieved. Furthermore, as is apparent from the comparison between Example 1 and Comparative Example 4, when a laser having a wavelength out of the wavelength region of ±30 nm from the absorption peak maximum wavelength of the nano-structured network is used, success/failure of the etching is changed. Namely, as disclosed in the present disclosure, the feature that the wavelength of the laser used for the etching and the absorption peak maximum wavelength of the nano-structured network constituting the transparent conducting layer, are in the mutually close wavelength region, is necessary for selectively etching the transparent conducting layer on one of the faces.

1. A transparent conducting film comprising a transparent resin film as a substrate, a first transparent conducting pattern layer provided on a first main face of the transparent resin film, a second transparent conducting pattern layer provided on a second main face of the transparent resin film and having a pattern different from the pattern of the first transparent conducting pattern layer, a first protection layer provided on the first transparent conducting pattern layer, and a second protection layer provided on the second transparent conducting pattern layer, respectively,
wherein, the first transparent conducting pattern layer has a first conducting region and a first non-conducting region,
the first conducting region contains a binder resin and a nano-structured network having metal nanowire intersections,
the second transparent conducting pattern layer has a second conducting region, the second conducting region containing a binder resin and a nano-structured network having metal nanowire intersections,
the first transparent conducting pattern layer has an absorption peak based on the nano-structured network, in an optical transmission spectrum,
the transparent resin film has a light transmittance of 80% or more in a wavelength region of ±30 nm from an absorption peak maximum wavelength based on the nano-structured network in the optical transmission spectrum and in a visible light region, and has a thickness of 40 μm or more.

2. A transparent conducting film according to claim 1, wherein the second transparent conducting pattern layer further comprises a second non-conducting region, and
the second transparent conducting pattern layer has an absorption peak based on the nano-structured network in the optical transmission spectrum.

3. A transparent conducting film according to claim 1, wherein the first non-conducting region contains a fragment of the nano-structured network having metal nanowire intersections.

4. A transparent conducting film according to claim 2, wherein the second non-conducting region contains a fragment of the nano-structured network having metal nanowire intersections.

5. A transparent conducting film according to claim 1, wherein the transparent resin film has a thickness of 200 μm or less.

6. A transparent conducting film according to claim 1, wherein the transparent resin film is a resin selected from a group consisting of a cyclo olefin polymer, polycarbonate, polyester, polyolefin, polyaramid, and acrylic resin.

7. A transparent conducting film according to claim 1, wherein, in the nano-structured network having metal nanowire intersections, at least a part of the metal nanowire intersections is fused.

8. A transparent conducting film according to claim 1, wherein the metal nanowire is a silver nanowire.

9. A transparent conducting film according to claim 1, wherein the binder resin is a homopolymer of N-vinylacetamide (NVA).

10. A transparent conducting film according to claim 1, wherein the first protection layer and the second protection layer are thermoset layers of a curable resin composition containing:
(A) polyurethane containing a carboxyl group,
(B) an epoxy compound having two or more epoxy groups in a molecule, and
(C) a curing accelerator.

11. A method for forming a transparent conducting pattern comprising:
a transparent conducting layer forming step for forming a first transparent conducting layer containing a binder resin and nano-structured network having metal nanowire intersections, on a first main face of a transparent resin film, and forming a second transparent conducting layer containing a binder resin and a nano-structured network having metal nanowire intersection, on a second main face of the transparent resin film, respectively,
a protection layer forming step for forming a first protection layer on the first transparent conducting layer, and forming a second protection layer on the second transparent conducting layer, respectively, and
a pattern forming step for forming a first transparent conducting pattern by etching only the first transparent conducting layer from the first protection layer side using pulse laser having a pulse width of shorter than 1 nanosecond,
wherein the first transparent conducting layer and the second transparent conducting layer respectively has an absorption peak based on the nano-structured network in an optical transmission spectrum, the transparent resin film has a light transmittance of 80% or more in a wavelength region of ±30 nm from an absorption peak maximum wavelength based on the nano-structured network in the optical transmission spectrum and in a visible light region, and has a thickness of 40 μm or more, and
the pulse laser has a wavelength within a range of ±30 nm from the absorption peak maximum wavelength based on the nano-structured network in the optical transmission spectrum.

12. A method for forming a transparent conducting pattern according to claim 11, further comprising a step for forming a second transparent conducting pattern by etching only the second transparent conducting layer from the second protection layer side using pulse laser having a pulse width of shorter than 1 nanosecond.
